(19) United States
(12) Patent Application Publication
(10) Pub. No.: US 2026/0096319 A1
(43) Pub. Date: Apr. 2, 2026

(54) DISPLAY DEVICE

(71) Applicant: LG Display Co., Ltd., Seoul (KR)

(72) Inventors: Seonghwan HWANG, Paju-si (KR); ByeongUk GANG, Paju-si (KR)

(73) Assignee: LG Display Co., Ltd., Seoul (KR)

(21) Appl. No.: 19/313,593

(22) Filed: Aug. 28, 2025

(30) Foreign Application Priority Data
Sep. 30, 2024 (KR) 10-2024-0132438

(51) Int. Cl. H10K 59/131; G09G 3/3225

(52) U.S. Cl. CPC H10K 59/131; G09G 3/3225; G09G 2300/0426; G09G 2300/0842

(57) ABSTRACT

A display device capable of reducing external light reflection by arranging signal lines supplying signals to sub-pixels on the same plane as the pixel electrode of the light-emitting device is described. The display includes signal lines—such as data lines, high-potential voltage lines, and reference voltage lines—formed in the same layer as the pixel electrode to minimize optical interference from stacked reflective materials. These lines are implemented as multi-layer structures comprising a transparent electrode material in a lower layer and a low-reflectance conductive material in an upper layer. A color filter is disposed below the pixel electrode and second signal lines to refract and reduce external light. Light-shielding lower patterns are arranged beneath gate lines and connection patterns. Transparent active layers of driving and sensing transistors serve as branch lines, enhancing optical performance and circuit compactness. This structure also improves process integration and manufacturing efficiency.

### CROSS REFERENCE TOO RELATED APPLICATION

This application claims priority from Korean Patent Application No. 10-2024-0132438, filed on Sep. 30, 2024, which is hereby incorporated by reference for all purposes as if fully set forth herein.

### BACKGROUND

### Technical Field

The present disclosure relates to a display device.

### Description of the Related Art

The display device is required to exhibit low reflectance to external light so that a user may easily recognize the displayed information even under conditions where external light is present.

The display device may include a plurality of pixels, each comprising a light-emitting device and various circuit elements for driving the light-emitting device. However, when external light is reflected by various material layers forming the light-emitting device and the circuit elements, a problem arises in that the user of the display device has difficulty recognizing the displayed information. To reduce the reflectance of external light, a polarizer or the like may be applied to the display device.

### BRIEF SUMMARY

While the application of a polarizer effectively reduces the reflectance of external light, the inventors of the present disclosure have recognized that it has certain drawbacks: the polarizer is a high-cost material, increasing the manufacturing cost of the display device; it limits the reduction of the display device's thickness; and the brightness of the light emitted from the light-emitting device decreases as the light passes through the polarizer.

Various embodiments of the present disclosure relate to a display device configured to significantly reduce external light reflection by reconfiguring the arrangement and materials of its internal components. Specifically, the signal lines (such as data lines, power lines, and reference voltage lines) are formed in the same plane and layer as the pixel electrode, using a combination of transparent conductive materials and low-reflectance metals. This co-planar structure reduces or minimizes light reflection caused by traditional multi-layer signal routing, while also enabling a more streamlined and unified fabrication process.

To further enhance anti-reflection performance, the display integrates color filters beneath both the pixel electrodes and signal lines. These filters refract incoming external light, reducing its intensity and preventing it from reflecting off metal layers. Additionally, transparent active layers are used as branch lines, and light-shielding floating layers are placed beneath reflective gate or connection lines. This holistic structural and material design achieves reduced external reflectance without sacrificing electrical performance or increasing device thickness.

For example, embodiments of the present disclosure may provide a display device that reduces external light reflection by arranging a main line, which supplies signals to subpixels, in the same layer as the pixel electrode of a light-emitting device.

Embodiments of the present disclosure may provide a display device that enables process optimization, simplification of materials for device components, and implementation of a unified (“Uni”) material product by forming the main line simultaneously with the pixel electrode.

Embodiments of the present disclosure may provide a display device that reduces external light reflection by applying a low-reflectance material to the main line.

Embodiments of the present disclosure may provide a display device that reduces external light reflection by applying a transparent line as a branch line of the main line.

Embodiments of the present disclosure may provide a display device that reduces external light reflection by applying a low-reflectance material beneath the gate line.

Embodiments of the present disclosure may provide a display device comprising: a substrate; a first signal line disposed on the substrate and extending in a first direction; an overcoat layer disposed on the first signal line; a pixel electrode disposed on the overcoat layer and comprising a first electrode material; a light-emitting layer disposed on the pixel electrode; a common electrode disposed on the light-emitting layer; and a plurality of second signal lines disposed on the overcoat layer, comprising the first electrode material, and extending in a second direction different from the first direction.

Embodiments of the present disclosure may provide a display device comprising: a substrate; a first signal line, which is a single-layer line, disposed on the substrate and extending in a first direction; an overcoat layer disposed on the first signal line; a pixel electrode of a light-emitting device disposed on the overcoat layer; and a plurality of second signal lines, which are multi-layer lines, disposed on the overcoat layer and extending in a second direction different from the first direction.

Embodiments of the present disclosure may provide a display device comprising: a substrate; a first signal line on the substrate; an overcoat layer on the first signal line; a pixel electrode of a light-emitting device on the overcoat layer; and a second signal line on the overcoat layer, wherein the pixel electrode and the second signal line are on a same layer as each other.

According to embodiments of the present disclosure, a display device that reduces external light reflection may be provided by arranging a main line, which supplies signals to subpixels, in the same layer as the pixel electrode of a light-emitting device.

According to embodiments of the present disclosure, a display device that enables process optimization, simplification of materials for device components, and implementation of a unified (“Uni”) material product may be provided by forming the main line simultaneously with the pixel electrode.

According to embodiments of the present disclosure, a display device that reduces external light reflection may be provided by applying a low-reflectance material to the main line.

According to embodiments of the present disclosure, a display device that reduces external light reflection may be provided by applying a transparent line as a branch line of the main line.

According to embodiments of the present disclosure, a display device that reduces external light reflection may be provided by applying a low-reflectance material beneath the gate line.

Additional technical benefits of the embodiments disclosed herein include improved light extraction efficiency and reduced power consumption.

The various embodiments described in the present disclosure reduce external light reflection while improving process optimization and simplifying materials.

### BRIEF DESCRIPTION OF THE SEVERAL VIEWS OF THE DRAWINGS

FIG. 1 is a diagram illustrating a display device according to embodiments of the present disclosure.

FIG. 2 is a diagram illustrating an example of a subpixel according to embodiments of the present disclosure.

FIG. 3 illustrates a plan view of an embodiment of the display device according to embodiments of the present disclosure.

FIG. 4 illustrates a cross-sectional view of an embodiment of the display device according to embodiments of the present disclosure.

FIG. 5 illustrates a more detailed plan view of an embodiment of the display device according to embodiments of the present disclosure.

FIG. 6 illustrates a cross-sectional view along line A-A′ in the plan view of FIG. 5.

FIG. 7 illustrates a cross-sectional view along line B-B′ in the plan view of FIG. 5.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

To further elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

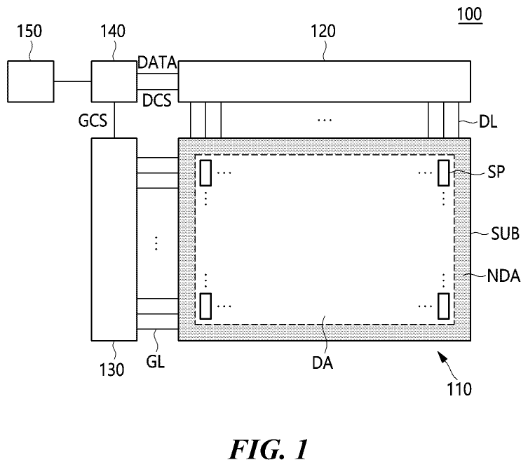

FIG. 1 is a diagram illustrating a display device 100 according to embodiments of the present disclosure.

Referring to FIG. 1, the display device 100 according to embodiments of the present disclosure may include a display panel 110 and a driving circuit for driving the display panel 110.

The driving circuit may include a data driving circuit 120 and a gate driving circuit 130 and may further include a controller 140 for controlling the data driving circuit 120 and the gate driving circuit 130.

The display panel 110 may include a substrate SUB and signal lines (also referred to as “lines”), such as a plurality of data lines DL and a plurality of gate lines GL disposed on the substrate SUB. The display panel 110 may also include a plurality of subpixels SP connected to the plurality of data lines DL and the plurality of gate lines GL.

The display panel 110 may include a display area DA in which an image is displayed and a non-display area NDA located outside the display area DA where no image is displayed. In the display panel 110, a plurality of subpixels SP for displaying an image are arranged in the display area DA, while the driving circuits 120, 130, and 140 may be electrically connected in or mounted on the non-display area NDA. A pad portion, to which an integrated circuit or a printed circuit, etc., may be connected, may also be disposed in the non-display area NDA.

The data driving circuit 120 is a circuit for driving the plurality of data lines DL and may supply data signals to the plurality of data lines DL. The gate driving circuit 130 is a circuit for driving the plurality of gate lines GL and may supply gate signals to the plurality of gate lines GL. The controller 140 may supply a data control signal DCS to the data driving circuit 120 to control the operation timing of the data driving circuit 120. The controller 140 may also supply a gate control signal GCS to the gate driving circuit 130 to control the operation timing of the gate driving circuit 130.

The controller 140 may control the scan operation to start according to the timing implemented in each frame and may convert input image data received from an external source (e.g., a host system 150) into a data signal format used by the data driving circuit 120. The controller 140 may then supply the converted image data DATA to the data driving circuit 120 and control the data driving operation to be performed at an appropriate time in synchronization with the scan timing.

The controller 140 may output various gate control signals GCS, including a gate start pulse GSP, a gate shift clock GSC, and a gate output enable signal GOE, to control the gate driving circuit 130.

The controller 140 may output various data control signals DCS, including a source start pulse SSP, a source sampling clock SSC, and a source output enable signal SOE, to control the data driving circuit 120.

The controller 140 may be implemented as a separate component from the data driving circuit 120 or may be integrated with the data driving circuit 120 into an integrated circuit.

The data driving circuit 120 receives image data DATA from the controller 140 and supplies data voltages to the plurality of data lines DL, thereby driving the plurality of data lines DL. The data driving circuit 120 is also referred to as a source driving circuit.

The data driving circuit 120 may include one or more source driver integrated circuits SDIC.

For example, each source driver integrated circuit SDIC may be connected to the display panel 110 using a tape automated bonding (TAB) method, may be connected to the bonding pad of the display panel 110 using a chip-on-glass (COG) or chip-on-panel (COP) method, or may be implemented using a chip-on-film (COF) method and connected to the display panel 110.

The gate driving circuit 130 may output a gate signal at a turn-on level voltage or a gate signal at a turn-off level voltage under the control of the controller 140. The gate driving circuit 130 may sequentially supply the gate signal at a turn-on level voltage to the plurality of gate lines GL, thereby sequentially driving the plurality of gate lines GL.

The gate driving circuit 130 may be connected to the display panel 110 using a tape automated bonding (TAB) method, may be connected to the bonding pad of the display panel 110 using a chip-on-glass (COG) or chip-on-panel (COP) method, or may be connected to the display panel 110 using a chip-on-film (COF) method. Alternatively, the gate driving circuit 130 may be formed in the non-display area NDA of the display panel 110 as a gate-in-panel (GIP) type. The gate driving circuit 130 may be disposed on or connected to the substrate SUB. For example, when implemented as a GIP type, the gate driving circuit 130 may be disposed in the non-display area NDA of the substrate SUB. When implemented as a chip-on-glass (COG) type or a chip-on-film (COF) type, the gate driving circuit 130 may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be arranged such that it does not overlap with the subpixels SP, or it may be arranged such that it partially or entirely overlaps with the subpixels SP.

When a specific gate line GL is turned on by the gate driving circuit 130, the data driving circuit 120 may convert the image data DATA received from the controller 140 into an analog data voltage and supply it to the plurality of data lines DL.

The data driving circuit 120 may be connected to one side of the display panel 110 (e.g., the upper or lower side). Depending on the driving method or panel design, the data driving circuit 120 may be connected to both sides of the display panel 110 (e.g., the upper and lower sides), or may be connected to two or more of the four sides of the display panel 110.

The gate driving circuit 130 may be connected to one side of the display panel 110 (e.g., the left or right side). Depending on the driving method or panel design, the gate driving circuit 130 may be connected to both sides of the display panel 110 (e.g., the left and right sides), or may be connected to two or more of the four sides of the display panel 110.

The controller 140 may be a timing controller commonly used in display technology or a control device capable of performing additional control functions, including the timing controller. The controller 140 may also be a control device separate from the timing controller or a circuit within the control device. The controller 140 may be implemented as various circuits or electronic components, such as an integrated circuit (IC), a field-programmable gate array (FPGA), an application-specific integrated circuit (ASIC), or a processor.

The controller 140 may be mounted on a printed circuit board or a flexible printed circuit and may be electrically connected to the data driving circuit 120 and the gate driving circuit 130 through the printed circuit board or the flexible printed circuit.

The display device 100 according to embodiments of the present disclosure may be a display that includes a backlight unit, such as a liquid crystal display (LCD), or a self-emitting display, such as an organic light-emitting diode (OLED) display, a quantum dot display, or a micro light-emitting diode (Micro LED) display.

If the display device 100 according to embodiments of the present disclosure is an OLED display, each subpixel SP may include an organic light-emitting diode (OLED) as a light-emitting device. If the display device 100 according to embodiments of the present disclosure is a quantum dot display, each subpixel SP may include a light-emitting device made of a quantum dot, which is a self-emitting semiconductor crystal. If the display device 100 according to embodiments of the present disclosure is a micro LED display, each subpixel SP may include a micro light-emitting diode (Micro LED), which is self-emitting and made of an inorganic material, as a light-emitting device.

The display panel 110 according to embodiments of the present disclosure may have a top emission structure or a bottom emission structure and, in some cases, may have a dual-sided emission structure.

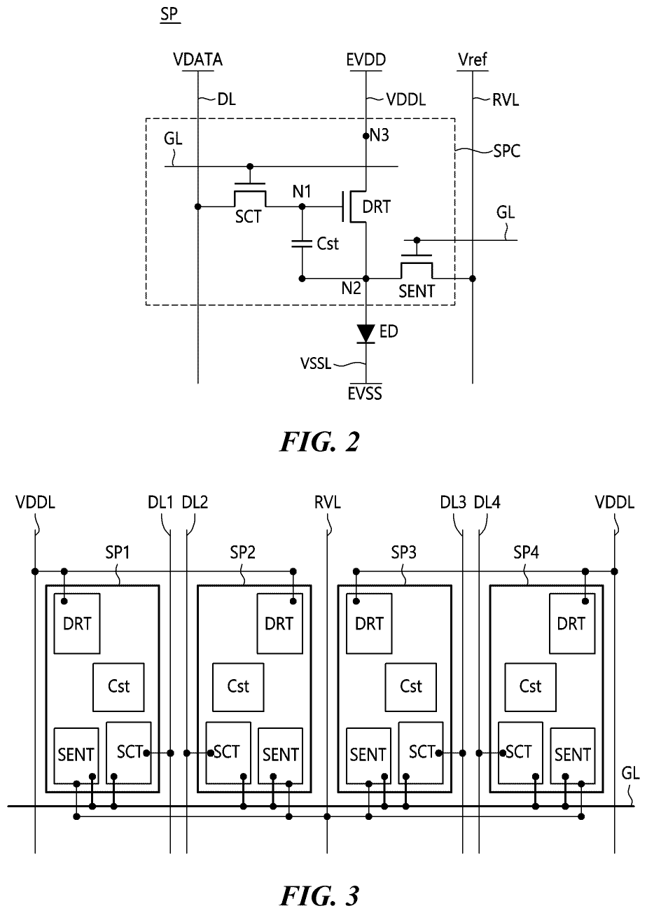

FIG. 2 is a diagram illustrating an example of a subpixel SP according to embodiments of the present disclosure.

Referring to FIG. 2, each subpixel SP according to embodiments of the present disclosure may include a light-emitting device ED and a subpixel circuit SPC configured to drive the light-emitting device ED.

Referring to FIG. 2, the subpixel circuit SPC may include a driving transistor DRT for driving the light-emitting device ED, a scan transistor SCT for transmitting a data voltage VDATA to a first node N1 of the driving transistor DRT, and a storage capacitor Cst for maintaining a constant voltage during one frame.

The light-emitting device ED may include a pixel electrode and a common electrode, and may further include a light-emitting layer positioned between the pixel electrode and the common electrode.

The pixel electrode of the light-emitting device ED may be an electrode arranged for each subpixel SP, while the common electrode may be an electrode commonly arranged for all subpixels SP. The pixel electrode may be an anode electrode, and the common electrode may be a cathode electrode. Conversely, the pixel electrode may be a cathode electrode, and the common electrode may be an anode electrode.

The common electrode of the light-emitting device ED may be connected to a low-potential voltage line VSSL, which applies a low-potential voltage EVSS.

For example, the light-emitting device ED may be an organic light-emitting diode (OLED), a light-emitting diode (LED), or a quantum dot light-emitting device.

The driving transistor DRT may be a transistor for driving the light-emitting device ED and may include a first node N1, a second node N2, and a third node N3.

The first node N1 of the driving transistor DRT may be a gate node of the driving transistor DRT and may be electrically connected to a source node or a drain node of the scan transistor SCT.

The second node N2 of the driving transistor DRT may be a source node or a drain node of the driving transistor DRT and may be electrically connected to the pixel electrode of the light-emitting device ED.

The third node N3 of the driving transistor DRT may be a drain node or a source node of the driving transistor DRT and may be electrically connected to a high-potential voltage line VDDL, which supplies a high-potential power voltage EVDD.

The storage capacitor Cst may be connected between the first node N1 and the second node N2 of the driving transistor DRT. The storage capacitor Cst functions to store an electric charge corresponding to the voltage difference between both terminals and to maintain the voltage difference for a predetermined frame time. Accordingly, the corresponding subpixel SP may emit light during the predetermined frame time.

The scan transistor SCT may be controlled by a gate signal and may be connected between the second node N2 of the driving transistor DRT and the data line DL.

The scan transistor SCT may be turned on by a gate signal at a turn-on level voltage supplied from the gate line GL and may transmit the data voltage VDATA supplied from the data line DL to the first node N1 of the driving transistor DRT.

In this case, when the scan transistor SCT is an n-type transistor, the turn-on level voltage of the gate signal may be a high-level voltage. When the scan transistor SCT is a p-type transistor, the turn-on level voltage of the gate signal may be a low-level voltage.

The sensing transistor SENT may be controlled by a gate signal and may be connected between the second node N2 of the driving transistor DRT and the reference voltage line RVL.

In other words, the sensing transistor SENT may be turned on by a gate signal at a turn-on level voltage supplied from the gate line GL and may control the connection between the reference voltage line RVL and the second node N2 of the driving transistor DRT.

The sensing transistor SENT may be turned on by a gate signal at a turn-on level voltage and may transmit a reference voltage Vref supplied from the reference voltage line RVL to the second node N2 of the driving transistor DRT.

Additionally, the sensing transistor SENT may be turned on by a gate signal at a turn-on level voltage and may transmit the voltage of the second node N2 of the driving transistor DRT to the reference voltage line RVL.

Here, when the sensing transistor SENT is an n-type transistor, the turn-on level voltage of the gate signal may be a high-level voltage. When the sensing transistor SENT is a p-type transistor, the turn-on level voltage of the gate signal may be a low-level voltage.

The function of the sensing transistor SENT to transmit the voltage of the second node N2 of the driving transistor DRT to the reference voltage line RVL may be used during operation to sense characteristics of the subpixel SP, such as the threshold voltage and mobility of the driving transistor DRT. In this case, the voltage transmitted to the reference voltage line RVL may be a voltage for calculating the characteristics of the subpixel SP or a voltage reflecting the characteristics of the subpixel SP.

Specifically, when the sensing transistor SENT transmits the voltage of the second node N2 of the driving transistor DRT to the reference voltage line RVL, the reference voltage line RVL may be connected to a power switch, a sampling switch, and an analog-to-digital converter (ADC).

The power switch may control the connection between the reference voltage line RVL and a reference voltage supply node. The reference voltage Vref output from a power supply may be supplied to the reference voltage supply node, and the reference voltage Vref supplied to the reference voltage supply node may be applied to the reference voltage line RVL through the power switch SPRE.

The sampling switch may control the connection between the analog-to-digital converter and the reference voltage line RVL. When the analog-to-digital converter is connected to the reference voltage line RVL by the sampling switch, it may convert the voltage (analog voltage) of the connected reference voltage line RVL into a sensing value corresponding to a digital value.

Meanwhile, the analog-to-digital converter may provide sensing data, including the sensing value, to a compensator.

The compensator may determine the characteristics of circuit elements included in the subpixel SP, such as the light-emitting device ED and the driving transistor DRT, based on the sensing data supplied from the analog-to-digital converter ADC. The compensator may calculate a compensation value to reduce characteristic variations among the circuit elements based on the characteristics and store the compensation value in a memory.

For example, the compensation value is information calculated to reduce characteristic variations among light-emitting devices ED or among driving transistors DRT and may include an offset and a gain for data modification.

The controller 140 may modify image data using the compensation value stored in the memory and supply the modified image data to the data driving circuit 120.

The data driving circuit 120 may use a digital-to-analog converter (DAC) to convert the modified image data DATA into a data voltage VDATA corresponding to an analog voltage and output the data voltage VDATA. Accordingly, compensation according to the characteristic sensing of the subpixel SP may be applied.

Referring to FIG. 2, the scan transistor SCT and the sensing transistor SENT may be connected to the same gate line GL. That is, in a single subpixel SP, the gate node of the scan transistor SCT and the gate node of the sensing transistor SENT may be connected to the same gate line GL. In this case, the on-off timing of the scan transistor SCT and the on-off timing of the sensing transistor SENT in the subpixel SP may be the same.

The scan transistor SCT and the sensing transistor SENT may also be connected to different gate lines GL. In this case, the scan transistor SCT may receive a scan gate signal at a turn-on level voltage from a scan gate line, which is a type of gate line GL, and control the connection between the data line DL and the first node N1 of the driving transistor DRT. The sensing transistor SENT may receive a sensing gate signal at a turn-on level voltage from a sensing gate line, which is another type of gate line GL, and control the connection between the reference voltage line RVL and the second node N2 of the driving transistor DRT.

When the scan transistor SCT and the sensing transistor SENT are connected to different gate lines GL, the scan gate signal and the sensing gate signal may be separate gate signals. The on-off timing of the scan transistor SCT and the on-off timing of the sensing transistor SENT in the subpixel SP may be independent of each other. That is, the on-off timing of the scan transistor SCT and the on-off timing of the sensing transistor SENT in the subpixel SP may be the same or different.

Each of the driving transistor DRT, the scan transistor SCT, and the sensing transistor SENT may be an n-type transistor or a p-type transistor. In the embodiments of the present disclosure, for the convenience of explanation, each of the driving transistor DRT, the scan transistor SCT, and the sensing transistor SENT is illustrated as an n-type transistor.

The storage capacitor Cst may be an external capacitor, which is intentionally designed outside the driving transistor DRT, rather than a parasitic capacitor (e.g., Cgs, Cgd), which is an internal capacitor existing between the gate node and the source node (or drain node) of the driving transistor DRT.

The structure of the subpixel SP shown in FIG. 2 is merely an example and may be variously modified to include one or more additional transistors or one or more additional capacitors.

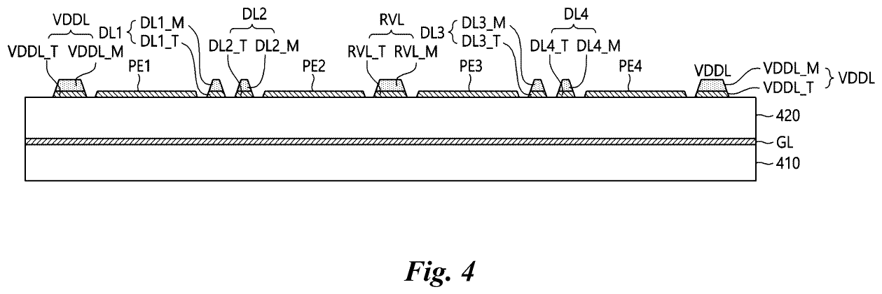

FIGS. 3 and 4 are diagrams illustrating an embodiment of the display device 100 according to embodiments of the present disclosure.

Specifically, FIG. 3 illustrates a plan view of an embodiment of the display device 100 according to embodiments of the present disclosure, and FIG. 4 illustrates a cross-sectional view of an embodiment of the display device 100 according to embodiments of the present disclosure.

Referring to FIG. 3, a plurality of subpixels SP included in the display device 100 may be arranged adjacent to each other and may include first to fourth subpixels SP1, SP2, SP3, and SP4, which emit different colors of light.

For example, the first subpixel SP1 may be a red subpixel that emits red light, the second subpixel SP2 may be a white subpixel that emits white light, the third subpixel SP3 may be a blue subpixel that emits blue light, and the fourth subpixel SP4 may be a green subpixel that emits green light. However, embodiments of the present disclosure are not limited thereto, and the colors of the first to fourth subpixels SP1, SP2, SP3, and SP4 may be variously modified through design changes.

When the first subpixel SP1 is a red subpixel, the first subpixel SP1 may include a light-emitting device ED that outputs white light and a red color filter.

When the third subpixel SP3 is a blue subpixel, the third subpixel SP3 may include a light-emitting device ED that outputs white light and a blue color filter.

When the fourth subpixel SP4 is a green subpixel, the fourth subpixel SP4 may include a light-emitting device ED that outputs white light and a green color filter.

When the second subpixel SP2 is a white subpixel, the second subpixel SP2 may include a light-emitting device ED that outputs white light.

In other words, when the second subpixel SP2 is a white subpixel, a color filter may not be disposed in the second subpixel SP2, unlike the first subpixel SP1, the third subpixel SP3, and the fourth subpixel SP4. However, embodiments of the present disclosure are not limited thereto.

The display device 100 may include a first signal line and a plurality of second signal lines arranged adjacent to the first to fourth subpixels SP1, SP2, SP3, and SP4.

The first signal line may be a single-layer line, and each of the plurality of second signal lines may be a multi-layer line.

Here, the term “multi-layer line” refers to a line that includes a first electrode layer based on a first electrode material and a second electrode layer based on a second electrode material, whereas “single-layer line” refers to a line that includes a third electrode layer based on a third electrode material. Hereinafter, the first electrode layer may be referred to as a lower line, and the second electrode layer may be referred to as an upper line.

Each of the first, second, and third electrode layers may be formed as either a single-layer structure composed of one layer based on at least one electrode material or a multi-layer structure composed of at least two layers.

For example, the first electrode material may include at least one of indium zinc oxide (IZO), indium tin oxide (ITO), indium gallium zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO). However, embodiments of the present disclosure are not limited thereto.

Additionally, the second electrode material may include at least one of copper (Cu) and tungsten oxide (WOx). However, embodiments of the present disclosure are not limited thereto.

Additionally, the third electrode material may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). However, embodiments of the present disclosure are not limited thereto.

The first signal line may include a gate line GL, and the plurality of second signal lines may include a high-potential voltage line VDDL, a data line DL, and a reference voltage line RVL. The plurality of second signal lines may be referred to as “main lines.”

According to the example in FIG. 3, the high-potential voltage line VDDL may be disposed on one side of the first subpixel SP1 and one side of the fourth subpixel SP4 and may be electrically connected to each of the first to fourth subpixels SP1, SP2, SP3, and SP4 to supply a high-potential power voltage EVDD.

The first data line DL1 and the second data line DL2 may be disposed between the first subpixel SP1 and the second subpixel SP2. The first data line DL1 may be electrically connected to the first subpixel SP1 to supply a data voltage VDATA, and the second data line DL2 may be electrically connected to the second subpixel SP2 to supply a data voltage VDATA.

The third data line DL3 and the fourth data line DL4 may be disposed between the third subpixel SP3 and the fourth subpixel SP4. The third data line DL3 may be electrically connected to the third subpixel SP3 to supply a data voltage VDATA, and the fourth data line DL4 may be electrically connected to the fourth subpixel SP4 to supply a data voltage VDATA.

The reference voltage line RVL may be disposed between the second subpixel SP2 and the third subpixel SP3 and may be electrically connected to each of the first to fourth subpixels SP1, SP2, SP3, and SP4 to supply a reference voltage Vref.

Referring to FIG. 4, the display device 100 may include a substrate 410 and an insulating layer 420 disposed on the substrate 410.

For example, the insulating layer 420 may be an overcoat layer. Hereinafter, for the convenience of explanation, the reference numeral 420 will be referred to as the overcoat layer.

The gate line GL may be disposed between the substrate 410 and the overcoat layer 420. The gate line GL may extend in a first direction.

The first pixel electrode PE1 of the first light-emitting device included in the first subpixel SP1, the second pixel electrode PE2 of the second light-emitting device included in the second subpixel SP2, the third pixel electrode PE3 of the third light-emitting device included in the third subpixel SP3, and the fourth pixel electrode PE4 of the fourth light-emitting device included in the fourth subpixel SP4 may be disposed on the overcoat layer 420 and may include a first electrode material.

For example, the first electrode material may be a transparent electrode material and may include at least one of indium zinc oxide (IZO), indium tin oxide (ITO), indium gallium zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO).

Each of the high-potential voltage line VDDL, the first to fourth data lines DL1, DL2, DL3, and DL4, and the reference voltage line RVL may be disposed on the overcoat layer 420, may include the first electrode material, and may extend in a second direction different from the first direction.

Each of the high-potential voltage line VDDL, the first to fourth data lines DL1, DL2, DL3, and DL4, and the reference voltage line RVL may include: a lower line (VDDL_T, DL1_T, DL2_T, DL3_T, DL4_T, RVL_T) including the first electrode material, and an upper line (VDDL_M, DL1_M, DL2_M, DL3_M, DL4_M, RVL_M) including a second electrode material different from the first electrode material, electrically connected to the lower line.

For example, the second electrode material may include at least one of copper (Cu) and tungsten oxide (WOx). In one example, the upper lines VDDL_M, DL1_M, DL2_M, DL3_M, DL4_M, and RVL_M may be implemented as copper (Cu) lines or dual-layer lines of copper (Cu) and tungsten oxide (WOx) (i.e., Cu/WOx). However, embodiments of the present disclosure are not limited thereto.

That is, the display device 100 according to embodiments of the present disclosure may have the high-potential voltage line VDDL, the first to fourth data lines DL1, DL2, DL3, and DL4, and the reference voltage line RVL disposed in the same layer as the pixel electrodes PE1, PE2, PE3, and PE4 of the light-emitting devices ED. Furthermore, by applying the second electrode material, which is a low-reflectance material, to the high-potential voltage line VDDL, the first to fourth data lines DL1, DL2, DL3, and DL4, and the reference voltage line RVL, external light reflection may be reduced.

Meanwhile, the display device 100 may further include a color filter disposed between the substrate 410 and the overcoat layer 420, and the color filter may overlap with at least one of the pixel electrodes PE1, PE2, PE3, and PE4 and the plurality of second signal lines.

Specifically, when the plurality of second signal lines is disposed adjacent to the substrate 410 and used as a light shield, the ratio of the light shield within the display device 100 increases. Since external light incident from below the substrate 410 is directly reflected by at least one of the plurality of second signal lines, there is a limitation in reducing the reflectance of external light.

In contrast, the display device 100 according to embodiments of the present disclosure applies the first electrode material, which is a pixel electrode material, to the second signal lines and arranges the plurality of second signal lines on the same plane as the pixel electrodes PE1, PE2, PE3, and PE4. This configuration avoids direct reflection of external light caused by the plurality of second signal lines and allows a color filter for light refraction to be disposed below the plurality of second signal lines. As a result, the intensity of external light can be reduced by the refraction effect of the color filter, thereby minimizing external light reflection.

The display device 100 may form the high-potential voltage line VDDL, the data lines DL1, DL2, DL3, and DL4, and the reference voltage line RVL together with the pixel electrodes PE1, PE2, PE3, and PE4.

For example, embodiments of the present disclosure may form the pixel electrodes PE1, PE2, PE3, and PE4, the high-potential voltage line VDDL, the data lines DL1, DL2, DL3, and DL4, and the reference voltage line RVL in the same layer by: patterning lower lines and upper lines in the pixel electrode formation area, the high-potential voltage line formation area, the data line formation area, and the reference voltage line formation area defined on the overcoat layer 420, and removing the patterned upper lines in the pixel electrode formation area.

Hereinafter, for the convenience of explanation, each of the pixel electrodes PE1, PE2, PE3, and PE4 of the first to fourth subpixels SP1, SP2, SP3, and SP4 may be referred to as a pixel electrode PXL.

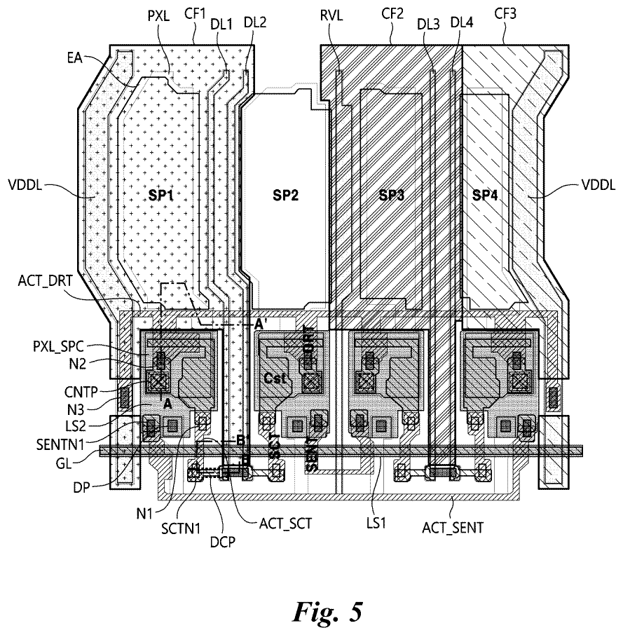

The display device 100 according to embodiments of the present disclosure will be further described in more detail through the embodiments shown in FIG. 5 to FIG. 7.

FIG. 5 to FIG. 7 are diagrams illustrating an embodiment of the display device 100 according to embodiments of the present disclosure in more detail.

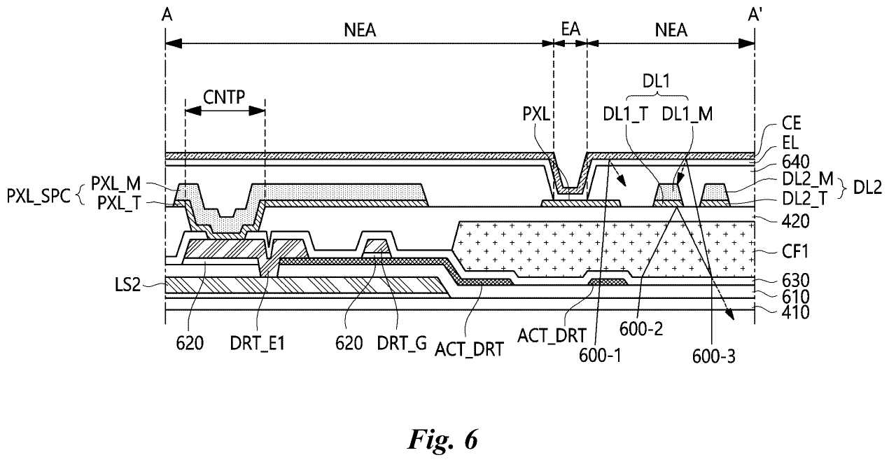

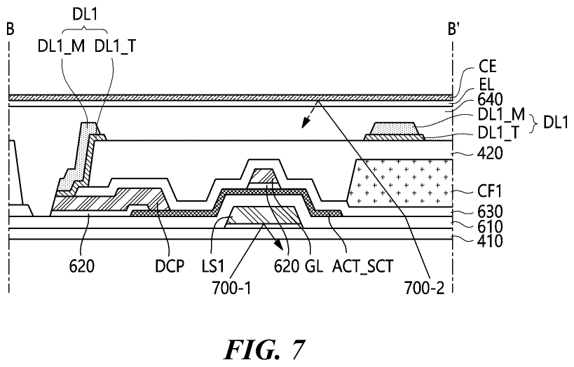

Specifically, FIG. 5 illustrates a more detailed plan view of an embodiment of the display device 100 according to embodiments of the present disclosure. FIG. 6 illustrates a cross-sectional view along line A-A′ in the plan view of FIG. 5. FIG. 7 illustrates a cross-sectional view along line B-B′ in the plan view of FIG. 5.

Referring to FIG. 5, a plurality of subpixels SP included in the display device 100 may be arranged adjacent to each other and may include first to fourth subpixels SP1, SP2, SP3, and SP4, which emit different colors of light.

The subpixel circuits SPC provided in each of the first to fourth subpixels SP1, SP2, SP3, and SP4 may be designed to have the same structure.

The subpixel circuits SPC of the first subpixel SP1 and the second subpixel SP2 may be designed to be symmetrical to each other, and the subpixel circuits SPC of the third subpixel SP3 and the fourth subpixel SP4 may be designed to be symmetrical to each other.

The display device 100 may include a first signal line extending in a first direction and a plurality of second signal lines extending in a second direction different from the first direction.

The first signal line may include a gate line GL, and the plurality of second signal lines may include a high-potential voltage line VDDL, data lines DL, and a reference voltage line RVL.

Referring to FIG. 2 and FIG. 5, each of the first to fourth subpixels SP1, SP2, SP3, and SP4 may include a driving transistor DRT for driving the light-emitting device ED, a scan transistor SCT for controlling the connection between the first node N1 of the driving transistor DRT and a corresponding one of the first to fourth data lines DL1, DL2, DL3, and DL4, and a sensing transistor SENT for controlling the connection between the second node N2 of the driving transistor DRT and the reference voltage line RVL.

Each of the first to fourth subpixels SP1, SP2, SP3, and SP4 may further include a dummy pattern DP formed in a region adjacent to the sensing transistor SENT.

The sensing transistor SENT may be electrically connected to the second node N2 of the driving transistor DRT through a source or drain node SENTN1 of the sensing transistor SENT.

The scan transistor SCT and the sensing transistor SENT may receive the same gate signal from the same gate line GL and may be turned on or off.

A first lower pattern LS1 may be disposed beneath the gate line GL, and the gate line GL and the first lower pattern LS1 may vertically overlap.

The first lower pattern LS1 may include the second electrode material, which is a low-reflectance material. Accordingly, reflection of external light incident from below the substrate 410 due to the gate line GL may be reduced.

The first lower pattern LS1 may be in an electrically floating state. In other words, the first lower pattern LS1 may function as a light shield for the gate line GL.

Additionally, the first lower pattern LS1 may overlap with at least one of a first active layer ACT_SCT of the scan transistor SCT and a third active layer ACT_SENT of the sensing transistor SENT. The first lower pattern LS1 may receive either the same signal as the signal transmitted from the gate line GL or a different signal.

For example, the first lower pattern LS1 may receive a first gate signal transmitted through the gate line GL from the gate driving circuit 130.

Additionally, the first lower pattern LS1 may receive a second gate signal different from the first gate signal transmitted through the gate line GL, from the gate driving circuit 130.

That is, the first lower pattern LS1 may function as a light shield for the gate line GL while also serving as a gate electrode of at least one of the scan transistor SCT and the sensing transistor SENT.

In other words, at least one of the scan transistor SCT and the sensing transistor SENT may be a double-gate transistor that includes both the first lower pattern LS1 and the gate line GL as gate electrodes.

The first node SCTN1 of the scan transistor SCT may be connected to a corresponding one of the first to fourth data lines DL1, DL2, DL3, and DL4 through a data connection pattern DCP.

For example, the data connection pattern DCP may be a drain electrode or a source electrode of the scan transistor SCT and may be formed of the same material as the gate line GL.

A third lower pattern may be disposed beneath the data connection pattern DCP, and at least a portion of the data connection pattern DCP and the third lower pattern may vertically overlap.

The third lower pattern may include the second electrode material, which is a low-reflectance material. Accordingly, reflection caused by the data connection pattern DCP due to external light incident from below the substrate 410 may be reduced.

Referring to FIG. 5, the second active layer ACT_DRT of the driving transistor DRT may be electrically connected to the high-potential voltage line VDDL, and the third active layer ACT_SENT of the sensing transistor SENT may be electrically connected to the reference voltage line RVL.

For example, the first active layer ACT_SCT, the second active layer ACT_DRT, and the third active layer ACT_SENT may be active layers including a transparent material and may include at least one of indium zinc oxide (IZO), indium tin oxide (ITO), indium gallium zinc oxide (IGZO), zinc oxide (ZnO), aluminum-doped zinc oxide (AZO), gallium-doped zinc oxide (GZO), antimony tin oxide (ATO), and fluorine-doped transparent oxides (FTO).

Specifically, the second active layer ACT_DRT may extend into a region where the high-potential voltage line VDDL is formed and may overlap at least a portion of the high-potential voltage line VDDL. The second active layer ACT_DRT may be electrically connected to the high-potential voltage line VDDL in the overlapped region, thereby forming the third node N3 of the driving transistor.

Additionally, the third active layer ACT_SENT may extend into a region where the reference voltage line RVL is formed and may overlap at least a portion of the reference voltage line RVL. The third active layer ACT_SENT may be electrically connected to the reference voltage line RVL in the overlapped region.

In other words, the display device 100 according to embodiments of the present disclosure may use the second active layer ACT_DRT and the third active layer ACT_SENT, which are active layers based on a transparent material, as branch lines of the high-potential voltage line VDDL and the reference voltage line RVL. By doing so, reflection of external light incident from below the substrate 410 may be reduced.

Referring to FIG. 5, a pixel electrode PXL may be disposed in the emission area EA of each of the first to fourth subpixels SP1, SP2, SP3, and SP4. The pixel electrode PXL may extend in the direction of the subpixel circuit SPC and may overlap with a portion of the second active layer ACT_DRT.

Each of the first to fourth subpixels SP1, SP2, SP3, and SP4 may include the first electrode material and may include an upper pattern layer PXL_SPC that overlaps at least a portion of the driving transistor DRT. The upper pattern layer PXL_SPC may be electrically connected to the pixel electrode PXL extending in the direction of the subpixel circuit SPC.

The upper pattern layer PXL_SPC may include a first upper pattern layer including the first electrode material and a second upper pattern layer including the second electrode material, the second upper pattern layer being electrically connected to the first upper pattern layer.

That is, the upper pattern layer PXL_SPC may be formed of the same material as the second signal lines, including the high-potential voltage line VDDL, the data lines DL1, DL2, DL3, and DL4, and the reference voltage line RVL.

In other words, the display device 100 according to embodiments of the present disclosure may have the upper pattern layer PXL_SPC disposed in the same layer as the pixel electrode PE1 [symbol] PE2 [symbol] PE3 [symbol] PE4 and the second signal lines. By applying the second electrode material, which is a low-reflectance material, to the upper pattern layer PXL_SPC, the reflection of external light may be reduced.

The display device 100 may form the plurality of second signal lines and the upper pattern layer PXL_SPC together with the pixel electrode PE1, PE2, PE3, PE4.

Each of the first to fourth subpixels SP1, SP2, SP3, and SP4 may overlap with at least a portion of the subpixel circuit SPC and may include a second lower pattern LS2, which contains the second electrode material as a low-reflectance material.

For example, the second lower pattern LS2 may overlap with at least a portion of the driving transistor DRT and at least a portion of the sensing transistor SENT.

That is, by arranging the second lower pattern LS2 overlapping at least a portion of the subpixel circuit SPC, the display device 100 according to embodiments of the present disclosure may reduce the reflection of external light incident from below the substrate 410.

Meanwhile, in each of the first to fourth subpixels SP1, SP2, SP3, and SP4, the first node N1 of the driving transistor DRT and the second lower pattern LS2 may overlap, thereby forming a storage capacitor Cst.

Referring to FIG. 5, the display device 100 may further include a color filter that overlaps with the pixel electrode PXL and at least one of the plurality of second signal lines. The color filter may be disposed beneath the pixel electrode PXL and the plurality of second signal lines.

For example, the first subpixel SP1 may include a first color filter CF1, the third subpixel SP3 may include a second color filter CF2, and the fourth subpixel SP4 may include a third color filter CF3.

For example, the first color filter CF1 may be a red color filter, the second color filter CF2 may be a blue color filter, and the third color filter CF3 may be a green color filter. However, embodiments of the present disclosure are not limited thereto.

According to the example in FIG. 5, the first color filter CF1 may be disposed in the emission area EA of the first subpixel SP1, overlapping with the pixel electrode PXL of the first subpixel SP1. The first color filter CF1 may extend from the emission area EA of the first subpixel SP1 and overlap with the high-potential voltage line VDDL, the first data line DL1, and the second data line DL2, which are adjacent to the first subpixel SP1 among the plurality of second signal lines.

The first color filter CF1 may overlap with at least a portion of the high-potential voltage line VDDL adjacent to the first subpixel SP1, at least a portion of the first data line DL1, and at least a portion of the second data line DL2.

Specifically, the first color filter CF1 may overlap with the high-potential voltage line VDDL adjacent to the first subpixel SP1. However, it may not overlap with the high-potential voltage line VDDL in a specific region where the second active layer ACT_DRT is electrically connected to the high-potential voltage line VDDL.

Additionally, the first color filter CF1 may overlap with the first data line DL1 and the second data line DL2. However, in specific regions where the first data line DL1 and the second data line DL2 are electrically connected to the data connection pattern DCP, the first color filter CF1 may not overlap with the first data line DL1 and the second data line DL2.

However, embodiments of the present disclosure are not limited thereto. The first color filter CF1 may overlap with the entire high-potential voltage line VDDL adjacent to the first subpixel SP1, the entire first data line DL1, or the entire second data line DL2.

The second color filter CF2 may be disposed in the emission area EA of the third subpixel SP3, overlapping with the pixel electrode PXL of the third subpixel SP3. The second color filter CF2 may extend from the emission area EA of the third subpixel SP3 and overlap with the reference voltage line RVL, the third data line DL3, and the fourth data line DL4 among the plurality of second signal lines.

The second color filter CF2 may overlap with at least a portion of the reference voltage line RVL, at least a portion of the third data line DL3, and at least a portion of the fourth data line DL4.

Specifically, the second color filter CF2 may not overlap with the reference voltage line RVL in a region adjacent to the subpixel circuit SPC of the third subpixel SP3.

Additionally, the second color filter CF2 may overlap with the third data line DL3 and the fourth data line DL4. However, in specific regions where the third data line DL3 and the fourth data line DL4 are electrically connected to the data connection pattern DCP, the second color filter CF2 may not overlap with the third data line DL3 and the fourth data line DL4.

However, embodiments of the present disclosure are not limited thereto. The second color filter CF2 may overlap with the entire reference voltage line RVL, the entire third data line DL3, or the entire fourth data line DL4.

The third color filter CF3 may be disposed in the emission area EA of the fourth subpixel SP4, overlapping with the pixel electrode PE of the fourth subpixel SP4. The third color filter CF3 may extend from the emission area EA of the fourth subpixel SP4 and overlap with the high-potential voltage line VDDL among the plurality of second signal lines.

According to the example in FIG. 5, the third color filter CF3 may overlap with at least a portion of the high-potential voltage line VDDL adjacent to the fourth subpixel SP4.

Specifically, the third color filter CF3 may overlap with the high-potential voltage line VDDL adjacent to the fourth subpixel SP4. However, it may not overlap with the high-potential voltage line VDDL in a specific region where the second active layer ACT_DRT is electrically connected to the high-potential voltage line VDDL.

However, embodiments of the present disclosure are not limited thereto. The third color filter CF3 may overlap with the entire high-potential voltage line VDDL adjacent to the fourth subpixel SP4.

Meanwhile, the high-potential voltage line VDDL adjacent to the fourth subpixel SP4 may also overlap with the first color filter CF1 of the first subpixel SP1.

Specifically, on one side of the fourth subpixel SP4, there is another first subpixel SP1 different from the first subpixel SP1 shown in FIG. 5. On the other side of the fourth subpixel SP4, the third subpixel SP3 shown in FIG. 5 may be located. In this case, at least a portion of the high-potential voltage line VDDL adjacent to the fourth subpixel SP4 may overlap with the first color filter CF1 of the first subpixel SP1 located on one side of the fourth subpixel SP4.

Referring to FIG. 6, the display device 100 according to embodiments of the present disclosure may include a substrate 410, a buffer layer 610 disposed on the substrate 410, a second insulating layer 630 disposed on the buffer layer 610, and an overcoat layer 420 disposed on the second insulating layer 630.

The display device 100 may include a pixel electrode PXL disposed on the overcoat layer 420 and including the first electrode material, a light-emitting layer EL disposed on the pixel electrode PXL, and a common electrode CE disposed on the light-emitting layer EL. The display device 100 may also include a first data line DL1 and a second data line DL2, which are disposed on the overcoat layer 420, include the first electrode material, and extend in a second direction.

The first data line DL1 may include a lower line DL1_T, which includes the first electrode material, and an upper line DL1_M, which includes the second electrode material and is electrically connected to the lower line DL1_T.

The second data line DL2 may include a lower line DL2_T, which includes the first electrode material, and an upper line DL2_M, which includes the second electrode material and is electrically connected to the lower line DL2_T.

The display device 100 may include a second lower pattern LS2 disposed between the substrate 410 and the buffer layer 610, a second active layer ACT_DRT of the driving transistor DRT disposed on the buffer layer 610, a first insulating layer 620 disposed on the second active layer ACT_DRT, a gate electrode DRT_G of the driving transistor DRT disposed on the first insulating layer 620, and a first electrode DRT_E1 of the driving transistor DRT electrically connected to a portion of the second active layer ACT_DRT.

For example, the first electrode DRT_E1 of the driving transistor DRT may be a source electrode or a drain electrode of the driving transistor.

For example, the first insulating layer 620, the second insulating layer 630, and the overcoat layer 420 may include silicon nitride (SiNx) or silicon oxide (SiO₂). However, embodiments of the present disclosure are not limited thereto.

The first insulating layer 620 may also be disposed between the buffer layer 610 and at least a portion of the first electrode DRT_E1 of the driving transistor DRT.

The second insulating layer 630 may be disposed on the buffer layer 610 and may be disposed to cover the first electrode DRT_E1 of the driving transistor DRT, the gate electrode DRT_G of the driving transistor DRT, and the second active layer ACT_DRT.

The first electrode DRT_E1 and the gate electrode DRT_G of the driving transistor DRT may overlap with the second lower pattern LS2, which includes the second electrode material as a low-reflectance material. Accordingly, reflection of external light incident from below the substrate 410 may be reduced.

A hole may be formed in a portion of the buffer layer 610 that overlaps with the first electrode DRT_E1 of the driving transistor DRT and the second lower pattern LS2. The first electrode DRT_E1 of the driving transistor DRT may be electrically connected to the second lower pattern LS2 through the hole in the buffer layer 610.

The second active layer ACT_DRT of the driving transistor DRT may be an active layer based on a transparent material and may be used as a branch line of the high-potential voltage line VDDL.

In other words, the display device may use the transparent second active layer ACT_DRT as a branch line of the high-potential voltage line VDDL. By doing so, as illustrated by reference numeral 600-1, reflection of external light incident from below the substrate 410 may be reduced.

The display device 100 may include the first color filter CF1 disposed between the second insulating layer 630 and the overcoat layer 420.

The first color filter CF1 may be disposed in the emission area EA of the first subpixel SP1, overlapping with the pixel electrode PE of the first subpixel SP1. The first color filter CF1 may extend into the non-emission area NEA of the first subpixel SP1 and may overlap with at least a portion of the first data line DL1 and the second data line DL2.

In other words, the display device 100 may arrange the first data line DL1 and the second data line DL2, which are second signal lines, in the same plane as the pixel electrode PE. The second electrode material, which is a low-reflectance material, may also be applied to the first data line DL1 and the second data line DL2. Furthermore, by disposing the first color filter CF1 beneath the first data line DL1 and the second data line DL2, reflection of external light incident from below the substrate 410 may be reduced.

According to the example in FIG. 6, the display device 100 may minimize the effect of external light reflection as external light incident from below the substrate 410, as illustrated by reference numeral 600-2, undergoes refraction through the first color filter CF1 and reflection by the upper lines DL1_M and DL2_T, thereby reducing the external light energy.

Additionally, as illustrated by reference numeral 600-3, the display device 100 may minimize the effect of external light reflection as external light incident from below the substrate 410 is refracted through the first color filter CF1, preventing reflection by the first data line DL1 and the second data line DL2, thus eliminating external light reflection.

The display device 100 may include an upper pattern layer PXL_SPC disposed on the overcoat layer 630 and overlapping with at least a portion of the driving transistor DRT.

The upper pattern layer PXL_SPC may include a first upper pattern layer PXL_T, which includes the first electrode material, and a second upper pattern layer PXL_M, which includes the second electrode material as a low-reflectance material and is electrically connected to the first upper pattern layer PXL_T. Accordingly, reflection of external light incident from below the substrate 410 in the direction of the driving transistor DRT may be reduced.

A contact hole CNTP may be formed in at least a portion of the region where the overcoat layer 420 and the second insulating layer 630 overlap with the upper pattern layer PXL_SPC and the first electrode DRT_E1 of the driving transistor DRT. The upper pattern layer PXL_SPC may be electrically connected to the first electrode DRT_E1 of the driving transistor DRT through the contact hole CNTP.

The display device 100 may further include a black bank layer 640 disposed between the overcoat layer 420 and the light-emitting layer EL. In some embodiments, a black bank layer 640 may be disposed between the substrate and the overcoat layer 420. The black bank layer 640 may be formed of a light-absorbing material such as black resin or black photoresist. At least a portion of the black matrix may vertically overlap with the first signal line (e.g., a gate line) to block or absorb light that would otherwise reflect off metal interconnects. This structure further contributes to reducing reflectance and enhancing image contrast.

Referring to FIG. 7, the display device 100 may include a first lower pattern LS1 disposed between the substrate 410 and the buffer layer 610, a first active layer ACT_SCT of the scan transistor SCT disposed on the buffer layer 610, a first insulating layer 620 disposed on the first active layer ACT_SCT, a gate line GL disposed on the first insulating layer 620, and a data connection pattern DCP electrically connected to a portion of the first active layer ACT_SCT.

For example, the gate line GL illustrated in FIG. 7 may be the gate electrode of the scan transistor SCT, and the data connection pattern DCP may be the drain electrode or the source electrode of the scan transistor SCT.

The first insulating layer 620 may also be disposed between the buffer layer 610 and at least a portion of the data connection pattern DCP.

The second insulating layer 630 may be disposed on the buffer layer 610 and may be arranged to cover the data connection pattern DCP, the gate line GL, and the first active layer ACT_SCT.

That is, the display device 100 may allow the gate line GL to overlap with the first lower pattern LS1, which includes the second electrode material as a low-reflectance material. Accordingly, as illustrated by reference numeral 700-1, the reflection of external light incident from below the substrate 410 due to the gate line GL may be reduced.

Additionally, by disposing the first color filter CF1 so that it overlaps with the first data line DL1, the display device 100 may minimize the effect of external light reflection. That is, as illustrated by reference numeral 700-2, external light incident from below the substrate 410 may be refracted through the first color filter CF1, thereby eliminating reflection by the first data line DL1.

The first lower pattern LS1 may overlap with the first active layer ACT_SCT and may receive the same signal as the one transmitted from the gate line GL or a different signal from the gate line GL.

For example, the first lower pattern LS1 may receive a first gate signal transmitted through the gate line GL from the gate driving circuit 130.

Additionally, the first lower pattern LS1 may receive a second gate signal, which is different from the first gate signal transmitted through the gate line GL, from the gate driving circuit 130.

In other words, the scan transistor SCT may be a double-gate transistor including both the first lower pattern LS1 and the gate line GL as gate electrodes.

The display device 100 may further include a third lower pattern disposed between the substrate 410 and the buffer layer 610 and overlapping with at least a portion of the data connection pattern DCP in the vertical direction.

The display device 100 may further include the third lower pattern beneath the data connection pattern DCP, where the third lower pattern includes the second electrode material as a low-reflectance material.

For example, the third lower pattern may include the second electrode material as a low-reflectance material. Accordingly, reflection of external light incident from below the substrate 410 due to the data connection pattern DCP may be reduced.

A summary of the embodiments described above is as follows.

A display device according to embodiments of the present disclosure may include a substrate; a first signal line disposed on the substrate and extending in a first direction; an overcoat layer disposed on the gate line; a pixel electrode disposed on the overcoat layer and including a first electrode material; a light-emitting layer disposed on the pixel electrode; a common electrode disposed on the light-emitting layer; and a plurality of second signal lines disposed on the overcoat layer, including the first electrode material and extending in a second direction different from the first direction.

The display device may further include a first lower pattern disposed on the substrate and a buffer layer disposed on the first lower pattern. The first signal line may be disposed on the buffer layer and may overlap with the first lower pattern in a vertical direction.

The first lower pattern may be in an electrically floating state.

The display device may further include a first active layer disposed on the buffer layer and overlapping with the first signal line, and a first insulating layer disposed on the first active layer. The first signal line may be disposed on the first insulating layer.

The first lower pattern may overlap with the first active layer and may receive the same signal as the one transmitted from the first signal line or a different signal from the first signal line.

The first signal line may be a single-layer line, and each of the plurality of second signal lines may be a multi-layer line.

Each of the plurality of second signal lines may include a lower line including the first electrode material and an upper line including the second electrode material, which is different from the first electrode material, wherein the upper line is electrically connected to the lower line.

The first electrode material may include a transparent electrode material.

The display device may further include a color filter disposed between the substrate and the overcoat layer. The color filter may overlap with the pixel electrode and at least one of the plurality of second signal lines.

The display device may include a first node, a second node, and a third node; a driving transistor electrically connected to a high-potential voltage line, which is one of the plurality of second signal lines, through the third node; a scan transistor turned on or off by a first signal transmitted from the first signal line and controlling the electrical connection between the data line, which is one of the plurality of second signal lines, and the first node; and a sensing transistor turned on or off by a first signal transmitted from the first signal line or by a signal different from the first signal, and controlling the electrical connection between the reference voltage line, which is one of the plurality of second signal lines, and the second node.

The display device may further include a third lower pattern disposed on the substrate, a buffer layer disposed on the third lower pattern, and a data connection pattern disposed on the buffer layer and electrically connecting the scan transistor and the data line. The data connection pattern may overlap with the third lower pattern in the vertical direction.

The driving transistor may include a second active layer, and the sensing transistor may include a third active layer. The second active layer may be electrically connected to the high-potential voltage line, and the third active layer may be electrically connected to the reference voltage line.

The display device may further include an upper pattern layer disposed on the overcoat layer, including the first electrode material, and overlapping with at least a portion of the driving transistor.

The display device may further include a color filter disposed between the substrate and the overcoat layer and overlapping with at least one of the plurality of second signal lines. The color filter may overlap with the high-potential voltage line but may not overlap with the high-potential voltage line in a designated area where the second active layer and the high-potential voltage line are electrically connected.

The upper pattern layer may include a first upper pattern layer including the first electrode material and a second upper pattern layer including a second electrode material different from the first electrode material, wherein the second upper pattern layer is electrically connected to the first upper pattern layer.

The display device according to embodiments of the present disclosure may include a substrate; a first signal line disposed on the substrate and extending in a first direction; an overcoat layer disposed on agate line; a pixel electrode of a light-emitting device disposed on the overcoat layer; and a plurality of second signal lines disposed on the overcoat layer and extending in a second direction different from the first direction. The first signal line may be a single-layer line, and each of the plurality of second signal lines may be a multi-layer line.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate;
a first signal line on the substrate and extending in a first direction;
an overcoat layer on the first signal line;
a pixel electrode on the overcoat layer, the pixel electrode comprising a first electrode material;
a light-emitting layer on the pixel electrode;
a common electrode on the light-emitting layer; and
a plurality of second signal lines on the overcoat layer, comprising the first electrode material, and extending in a second direction different from the first direction.

2. The display device of claim 1, further comprising:
a first lower pattern on the substrate; and
a buffer layer on the first lower pattern,
wherein the first signal line is on the buffer layer and vertically overlaps the first lower pattern.

3. The display device of claim 2, wherein the first lower pattern is in an electrically floating state.

4. The display device of claim 2, further comprising:
a first active layer on the buffer layer and overlapping the first signal line; and
a first insulating layer on the first active layer,
wherein the first signal line is on the first insulating layer.

5. The display device of claim 4, wherein the first lower pattern overlaps the first active layer and transmits a signal that is the same as or different from the signal transmitted through the first signal line.

6. The display device of claim 1, wherein the first signal line is a single-layer line, and each of the plurality of second signal lines is a multi-layer line.

7. The display device of claim 1, wherein each of the plurality of second signal lines comprises:
a lower line including the first electrode material; and
an upper line including a second electrode material different from the first electrode material and electrically connected to the lower line.

8. The display device of claim 7, wherein the upper line includes a low-reflectance material.

9. The display device of claim 1, wherein the first electrode material comprises a transparent electrode material.

10. The display device of claim 1, further comprising a color filter disposed between the substrate and the overcoat layer, and
wherein the color filter overlaps the pixel electrode and at least one of the plurality of second signal lines.

11. The display device of claim 1, further comprising:
a driving transistor including a first node, a second node, and a third node, wherein the third node is electrically connected to a high-potential voltage line among the plurality of second signal lines;
a scan transistor that is turned on or off by a first signal transmitted through the first signal line and controls the electrical connection between a data line among the plurality of second signal lines and the first node; and
a sensing transistor that is turned on or off by the first signal transmitted from the first signal line or a signal different from the first signal and controls the electrical connection between a reference voltage line among the plurality of second signal lines and the second node.

12. The display device of claim 11, further comprising:
a third lower pattern disposed on the substrate;
a buffer layer disposed on the third lower pattern; and
a data connection pattern disposed on the buffer layer and electrically connecting the scan transistor and the data line,
wherein the data connection pattern vertically overlaps the third lower pattern.

13. The display device of claim 11, wherein the driving transistor comprises a second active layer, the sensing transistor comprises a third active layer, the second active layer is electrically connected to the high-potential voltage line, and the third active layer is electrically connected to the reference voltage line.

14. The display device of claim 11, further comprising an upper pattern layer disposed on the overcoat layer, including the first electrode material, and overlapping at least a portion of the driving transistor.

15. The display device of claim 13, further comprising a color filter disposed between the substrate and the overcoat layer and overlapping at least one of the plurality of second signal lines, and
wherein the color filter overlaps the high-potential voltage line but does not overlap the high-potential voltage line in a predetermined region where the second active layer is electrically connected to the high-potential voltage line.

16. The display device of claim 14, wherein the upper pattern layer comprises:
a first upper pattern layer including the first electrode material; and
a second upper pattern layer including a second electrode material different from the first electrode material and electrically connected to the first upper pattern layer.

17. The display device of claim 1, further comprising: at least one of a driving transistor and a sensing transistor including an active layer,
wherein the active layer includes a transparent material that electrically connects to one of the plurality of second signal lines as a branch line.

18. A display device comprising:
a substrate;
a first signal line on the substrate and extending in a first direction;
an overcoat layer on the first signal line;
a pixel electrode of a light-emitting device on the overcoat layer; and
a plurality of second signal lines on the overcoat layer and extending in a second direction different from the first direction,
wherein the first signal line is a single-layer line, and each of the plurality of second signal lines is a multi-layer line.

19. A display device comprising:
a substrate;
a first signal line on the substrate;
an overcoat layer on the first signal line;
a pixel electrode of a light-emitting device on the overcoat layer; and
a second signal line on the overcoat layer,
wherein the pixel electrode and the second signal line are on a same layer as each other.

20. The display device of claim 19, further comprising a black bank layer between the substrate and the overcoat layer, wherein the black bank layer at least partially overlaps the first signal line.
